(19) United States
(12) Patent Application Publication
(10) Pub. No.: US 2004/0115878 A1
(43) Pub. Date: Jun. 17, 2004

(54) Method for manufacturing a silicon germanium based device with crystal defect prevention

(75) Inventors: Kuen-Chyr Lee, Hsin-Chu (TW); Liang-Gi Yao, Hsin-Chu (TW); Chi-Chun Chen, Kaohsiung (TW); Shin-Chang Chen, Hsin-Chu (TW); Mong-Song Liang, Hsin-Chu (TW)

Correspondence Address: HAYNES AND BOONE, LLP, 901 MAIN STREET, SUITE 3100, DALLAS, TX, 75202, US

(73) Assignee: Taiwan Semiconductor Manufacturing Co., LTD, Hsin-Chu (TW)

(21) Appl. No.: 10/319,112

(22) Filed: Dec. 13, 2002

(51) Int. Cl. H01L 21/8238

(52) U.S. Cl. 438/202; 438/312

(57) ABSTRACT

The present disclosure provides a method for forming and manufacturing a silicon germanium (SiGe) based device. After forming a substrate of the device and forming one or more layers of semiconductor processing materials in one or more predetermined locations to establish an opening for depositing one or more SiGe material layers, a pre-baking process is applied to the device under a low pressure not to exceed 79 torr and 900° C. Once completed, the one or more SiGe material layers are deposited and other conventional steps are taken to complete the manufacturing of the device.

### BACKGROUND

The present disclosure relates generally to the fabrication of semiconductor devices, and more particularly, to a method and process for forming silicon germanium (SiGe) based devices such as heterojunction bipolar transistor (HBT) with crystal defect prevention.

Transistors are the fundamental device units for all electronic circuits and are typically used as either amplifying or switching devices. In the first application, the transistor functions to amplify small ac signals. In the second application, a small current is used to switch the transistor between an “on” state and an “off” state.

The bipolar transistor is an electronic device with two n-p junctions in close proximity. The bipolar transistor has three device regions: an emitter, a collector, and a base disposed between the emitter and the collector. Ideally, the two p-n junctions (the emitter-base and collector-base junctions) are in a single layer of semiconductor material separated by a specific distance. External leads can be attached to each of the three regions and external voltages and currents can be applied to the device using these leads. If the emitter and collector are doped n-type and the base is doped p-type, the device is an “npn” transistor. Alternatively, if the opposite doping configuration is used, the device is a “pnp” transistor. Because the mobility of minority carriers (i.e., electrons) in the base region of npn transistors is higher than that of holes in the base of pnp transistors, higher-frequency operation and higher-speed performances can be obtained with npn devices. Therefore, npn transistors comprise the majority of bipolar transistors used to build integrated circuits.

As the vertical dimensions of the bipolar transistor are scaled more and more, serious device operational limitations have been encountered. One actively studied approach to overcome these limitations is to build transistors with emitter materials whose band gaps are larger than the band gaps of the material used in the base. Such structures are called heterojunction transistors. Heterostructures comprising heterojunctions can be used for both majority carrier and minority carrier devices. Among majority carrier devices, heterojunction bipolar transistors in which the emitter is formed of silicon and the base of a silicon-germanium alloy have recently been developed. The silicon-germanium alloy (often expressed simply as silicon-germanium) is narrower in band gap than silicon.

The use of silicon-germanium for the base can enhance the efficiency of carrier injection from the emitter into the base and, in consequence, current gain “g” becomes sufficiently high even though the impurity concentration in the silicon-germanium base is made higher than that in the conventional silicon base by more than one order of magnitude. With a silicon-germanium base, high performance at high frequencies can be realized by sufficiently raising the doping level in the base and reducing the base width. Furthermore, there is a possibility of improving the cut-off frequency (shortening the emitter-base diffusion time, .tau..sub.ed) and, consequentially, further enhancing the high-frequency characteristics by grading the germanium profile in the silicon-germanium base.

The advanced silicon-germanium bipolar complementary metal-oxide-semiconductor (BiCMOS) technology uses a silicon-germanium base in the heterojunction bipolar transistor. In the high frequency (such as multi-GHz) regime, conventional compound semiconductors such as GaAs and InP currently dominate the market for high speed wired and wireless communications. Silicon-germanium BiCMOS promises not only a comparable performance to GaAs in devices such as power amplifiers, but also a substantial cost reduction due to the integration of heterojunction bipolar transistors with standard CMOS, yielding the so-called “system on a chip.”

SiGe heterojunction bipolar transistors(HBTs) have attracted much attention because of both the device performance and the low cost for many applications. However, there is a concern for crystal defect during SiGe deposition resulted from SiO₂ residue which increases the failure percentage(based on the breakdown voltage between emitter and collector (BVceo)) of an HBT.

In order to produce high speed (HB) devices, the conventional SiGe material may not be ideal. Silicon germanium carbide (SiGeC) is used for the reason that it would provide a faster switching speed. Another solution is to increase the dosage in the implantation to increase the speed. While increasing the implant dosage will enhance the speed, It creates a damaged EPI surface (which is known as the lattice defects) of the collector area before the SiGe deposition.

What is needed is an improved process to prevent the crystal defect for using SiGe material to form semiconductor devices.

### SUMMARY

The present disclosure provides a method for forming and manufacturing a silicon germanium (SiGe) based device. After forming a substrate of the device and forming one or more layers of semiconductor processing materials in one or more predetermined locations to establish an opening for depositing one or more SiGe material layers, a pre-baking process is applied to the device under a low pressure not to exceed 79 torn. Once completed, the one or more SiGe material layers are deposited and other conventional steps are taken to complete the manufacturing of the device. The above process is used to create a SiGe based devices such as SiGe BJT devices and HBTs.

With the pre-baking process, the crystal defect problem is avoided. No thermal budget of the MOS region is breached, and the throughput of SiGe deposition process is not detrimentally impacted.

### BRIEF DESCRIPTION OF THE DRAWINGS

FIG. 1 illustrates a SiGe based device in the manufacturing process before the SiGe deposition.

FIG. 2 illustrates a SiGe based device in the manufacturing process before the SiGe deposition.

FIG. 3 is a basic process flow chart identifying key steps for making such an HS single device.

FIG. 4 illustrates a failure assessment chart for the device with different pressure condition for a pre-baking process.

### DETAILED DESCRIPTION OF THE PREFERRED EMBODIMENTS

The present disclosure can be described by the embodiments given below. It is understood, however, that the embodiments below are not necessarily limitations to the present disclosure, but are used to describe a typical implementation of the invention.

As discussed above, there is a need to manufacture SiGe based device with prevention for crystal defects. Especially for high speed devices, it is desirable to use SiGe instead of SiGeC or other materials.

FIG. 1 illustrates a sample layout 100 of a single-device BJT in processing. In the center is the N-silicon material such as epitaxial (EPI) film 102; which is sandwiched by two shallow trench isolation (STI) areas 104 and 106. The EPI area 102 is going to be the collector region of the BJT device when the device is finished with all processing steps. In order to define the BJT window, an oxide layer 108 is first deposited on the STI areas as to isolate the BJT device to be processed on the window from neighboring semiconductor materials. The oxide can be deposited by conventional deposition methods such as chemical vapor deposition using Tetraethyl Orthosilicate (TEOS). On top of the oxide layer 108, another polysilicon material layer 110 is deposited. When this is completed, the BJT window is defined clearly in the middle as shown.

In the conventional method for making a SiGe based device, the SiGe material is then deposited on top of N-EPI film 102 to form the base electrode area. If the device requires its speed parameter fT to be improved like in the high speed devices, the phosphorous doping needs to be heavier in the collector region. As the implant dosage increases, the level of lattice/crystal defects increases too caused by residual oxides (e.g. SiO₂) on the surface of the collector region. The residual SiO₂ might be from several sources such as the native oxide created after an HF wet dip process but before a baking process, or the thermal oxide created during the baking process such as the H₂ baking process with a trace material such as O₂.

As it is known in the art, the H₂ pre-baking process is designed for oxide removal, but the H₂ pre-baking process at a wrong pressure and wrong temperature for HS devices will actually help thermal oxide generation. For example, the growth rate of thermal oxide will be larger than that of the native oxide removal at a pressure larger than 760 torr. In another words, devices with higher implant energy and dosage will result in lattice defect at the EPI collector surface, which may subsequently inhibits the native oxide removal and enhances the thermal oxide growth.

As it is clearly demonstrated that the residual oxides are the root cause of the crystal defects, which bring undesired effect such as the increased failure rate based on BV_{ceo}. The crystal defect problem may be dealt with by increasing an H₂ pre-baking temperature or duration, but such a solution increases the total thermal budget allowed for MOS regions situated next to the BJT window on the same substrate and also decreases the throughput of manufacturing lines.

The present invention introduces a law pressure hydrogen pre-baking process to resolve the issue of crystal defects without increasing the total thermal budget for the device under the process. Continuing from the state illustrated by FIG. 1, the device is going through a designed low pressure hydrogen pre-baking process in which the pressure is kept at 1-79 torr depending on the variation of the fT value expected for different devices and a temperature lower than 900° C. so that the growth rate of the thermal oxide such as SiO₂, resulted from trace moisture and oxygen in H₂ pre-baking process and the reaction chamber, is decreased and the removal rate of the native oxide is increased. Preferably, the pressure is kept below 50 torr, and in an ideal case, the pressure should be kept below 10 torr. The duration of this process can vary in a great deal depending on the devices, but may be between 1-10 minutes.

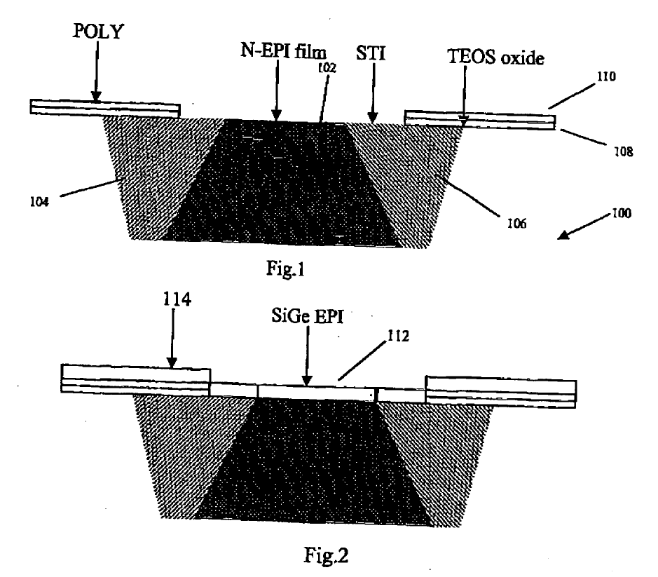

After the low pressure hydrogen pre-baking process, the SiGe material is deposited as illustrated in FIG. 2 and the BJT device will be completed step by step as in the conventional methods. For example, a SiGe material is deposited on top of the N-EPI film so that a base region 112 of the BJT device is formed, and the SiGe material layer 114 is also deposited on top of the remaining STI areas and the polysilicon areas.

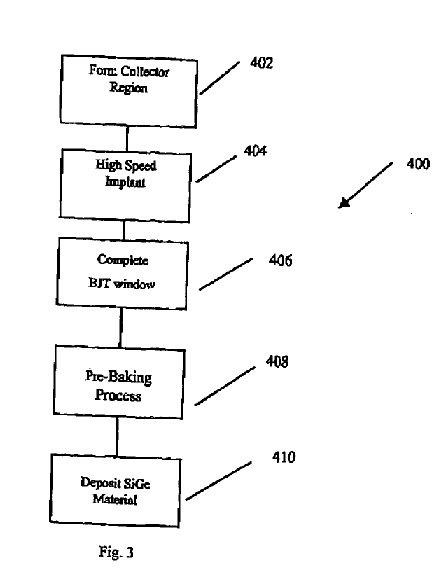

FIG. 3 is a basic process flow chart 400 identifying key steps for making such an HS single device. In step 402, a collector region is formed by As doping. Subsequently, a P-type doping process such as high speed implant is done to the same region in step 404. In the next step (406), a BJT window is formed by having TEOS deposition and polysilicon deposition. During the BJT window forming process, the deposited polysilicon will have gone through a dry etch process to have an appropriate thickness and a wet dip process using HF for cleaning the TEOS oxide. In step 408, an H₂ pre-baking process is carried out to reduce the possibility of crystal defects. The H₂ pre-baking process is conducted with a pressure not to exceed 100 torr and at a temperature not to exceed 900° C. After that, the SiGe layer is deposited over the polysilicon and the BJT window in step 410. Thereafter, the device is completed with other necessary processes to form a BJT device.

It is understood that the above process is generic for making SiGe device with a prevention mechanism for crystal defects. The detailed arrangement for the process may be implemented differently based on the various design of the devices under construction.

For instance, HS devices with high implant energy (such as those more than 320 kev) and high dosages (such as those higher than 1E3/cm²) will result in more severe lattice defect at the EPI collector surface, that might inhibit native oxide removal and enhance thermal oxide growth. Consequently, it needs very low pressure such as 10 torr during the H₂ pre-baking and a longer duration.

For standard devices, medium implant energy and dosage also will result in significant lattice defect at the EPI collector surface, that also might inhibit native oxide removal and enhance thermal oxide growth. Accordingly, it also needs low pressure (such as 50 torr to 80 torr) during tie H₂ pre-baking and relatively long duration.

For high voltage devices which does not require an implant process after the collector area formation, there will be lattice defect at the collector surface as well although to a much lesser extent. In this case, it just needs an ATM(760 torr) pressure for the H₂ pre-baking process.

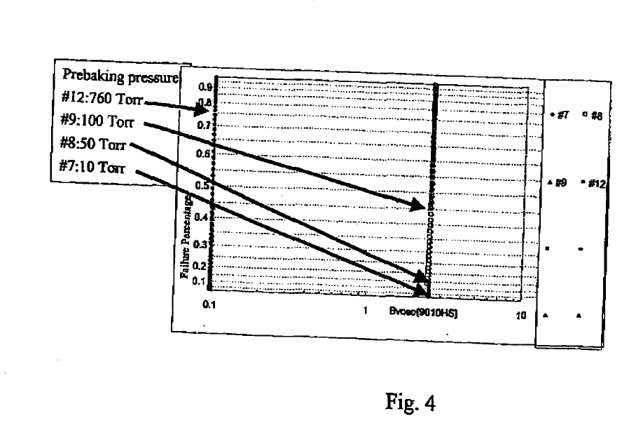

FIG. 4 is a failure percentage assessment chart based on the measurements of BV_{ceo} of the HS single device at various H₂ pre-baking condition. As shown, when the pressure is kept under 50 torr, the failure percentage is roughly under 20%, which may be acceptable for some devices, but when the pressure goes up, the failure percentage become large. It should be noted that if possible, the pressure should be kept at a very low point since it tends to produce the best results, When the pressure is reduced around or under 10 torr, the failure rates dropped drastically.

As described above, with the pre-baking process, the crystal defect problem is avoided. No thermal budget of the MOS region is breached, and the throughput of SiGe deposition process is not detrimentally impacted.

It is noted that although the example shown above is a single device, the low pressure pre-baking process can be applied to any SiGe based device to reduce the residual native oxide or thermal oxide.

It is understood that several modifications, changes and substitutions are intended in the foregoing disclosure and in some instances some features of the invention will be employed without a corresponding use of other features. Accordingly, it is appropriate that the appended claims be construed broadly and in a manner consistent with the scope of the invention.

1. A method for manufacturing a silicon germanium (SiGe) based device using bipolar complementary metal-oxide semiconductor (BiCMOS) technology, the method comprising:
forming a substrate of the device with one or more predetermined manufacturing processes including an implantation process;
forming one or more layers of semiconductor processing materials in one or more predetermined locations to establish an opening for depositing one or more SiGe material layers;
pre-baking the device under a low pressure not to exceed 79 torr and a temperature not to exceed 900° C.; and
depositing the one or more SiGe material layers.

2. The method of claim 1 wherein the SiGe based device is a heterojunction bipolar transistor.

3. The method of claim 1 wherein the pre-baking lasts about 3 minutes.

4. The method of claim 1 wherein the pre-baking is under a hydrogen environment with the pressure lower than 50 torr.

5. The method of claim 1 wherein the implantation process has an energy level higher than 320 kev.

6. The method of claim 1 wherein the implantation process has a dosage higher than 1E3/cm².

7. The method of claim 1 wherein the low pressure is below 10 torr.

8. The method of claim 1 further comprising depositing one or more semiconductor materials after the pre-baking the device to complete the manufacturing of the device.

9. A method for manufacturing a high speed silicon germanium (SiGe) based device, comprising:
forming a substrate of the device with one or more predetermined manufacturing processes including an implantation process;
establishing an opening on the substrate for completing the high speed SiGe based device;
pre-baking the device under a predetermined low pressure not to exceed 50 torr and a temperature not to exceed 900° C.; and
depositing the one or more SiGe material layers to complete the high speed SiGe based device.

10. The method of claim 9 wherein the high speed SiGe based device is a bipolar transistor.

11. The method of claim 9 wherein the pre-baking lasts between 3 to 10 minutes.

12. The method of claim 9 wherein the pre-baking is under a hydrogen environment.

13. The method t claim 9 wherein the implantation process has an energy level higher than 320 kev.

14. The method of claim 9 wherein the implantation process has a dosage higher than 1E3/cm².

15. The method of claim 9 wherein the predetermined pressure is below 10 torr.

16. The method of claim 9 wherein the predetermined pressure is below 20 torr.

17. The method of claim 9 wherein the temperature is below 850° C.

18. A method for manufacturing a silicon germanium (SiGe) based heterojunction bipolar transistor using bipolar complementary metal-oxide semiconductor (BiCMOS) technology, comprising:
forming a substrate of the device using at least one implantation process;
establishing an opening for depositing one or more SiGe material layers,
pre-baking the device under a relatively low pressure not to exceed 20 torr and a temperature not to exceed 900° C.; and
depositing the one or more SiGe material layers,
wherein the pre-baking is under a hydrogen environment.

19. The method of claim 18 wherein the implantation process has an energy level higher than 320 kev.

20. The method of claim 18 wherein the implantation process has a dosage higher than 1E3/cm².

21. The method of claim 18 wherein the device is a high speed device.

22. The method of claim 18 further comprising depositing one or more semiconductor materials after the pre-baking the device to complete the manufacturing of the device.
